(19) United States
(12) Patent Application Publication
(10) Pub. No.: US 2026/0016549 A1
(43) Pub. Date: Jan. 15, 2026

(54) POWER HEALTH MONITORING ASSEMBLY FOR A POWER CONNECTOR

(71) Applicant: TE Connectivity Solutions GmbH, Schaffhausen (CH)

(72) Inventor: Richard Carreno, Fremont, CA (US)

(21) Appl. No.: 18/768,530

(22) Filed: Jul. 10, 2024

(51) Int. Cl. G01R 31/58; G01R 19/165

(52) U.S. Cl. CPC G01R 31/58; G01R 19/16576

(57) ABSTRACT

A power cable assembly includes a power cable that has wires. The power cable assembly includes a power connector that has a connector body holding power terminals terminated to ends of the corresponding power wires forming power lines for the power cable assembly. The power terminals include mating ends configured to be mated with mating terminals of a mating connector. The power connector includes a power health monitoring assembly. The power health monitoring assembly includes indicators operably coupled to each of the power terminals. The indicators generate visible light and provide a visual indication of a power health of the corresponding power line visible from an exterior of the power connector.

### BACKGROUND OF THE INVENTION

The subject matter herein relates generally to power connectors.

Power connectors are used in various applications and industries to provide power for devices. When the voltage or amperage on the power lines through the power connectors drop or spike, the equipment may be damaged. For example, components of the device may be damaged by the drop or spike in loads. The damage can occur over time and may not be instantaneous. It is difficult to assess the power health characteristics of the power supply through the wires and terminals in the system.

There is a need to assess the power health characteristics of the power system along the power lines of a power connector to prevent damage to devices connected to the power connector.

### BRIEF DESCRIPTION OF THE INVENTION

In one embodiment, a power cable assembly is provided and includes a power cable that has wires. The power cable assembly includes a power connector that has a connector body holding power terminals terminated to ends of the corresponding power wires forming power lines for the power cable assembly. The power terminals include mating ends configured to be mated with mating terminals of a mating connector. The power connector includes a power health monitoring assembly. The power health monitoring assembly includes indicators operably coupled to each of the power terminals. The indicators generate visible light and provide a visual indication of a power health of the corresponding power line visible from an exterior of the power connector.

In another embodiment, a power connector is provided and includes a connector body that has a mating end configured to be mated with a mating connector. The connector body includes an outer surface. The connector body includes terminal channels. The power connector includes power terminals received in the terminal channels. The power terminals include terminating ends and mating ends opposite the terminating ends. The mating ends configured to be mated with mating terminals of the mating connector. The power terminals form discrete power lines through the power connector. The power connector includes a power health monitoring assembly held by the connector body. The power health monitoring assembly includes indicators operably coupled to each of the power terminals, light from the indicators being visible at the outer surface of the connector body to provide a visual indication of a power health of the corresponding power line.

In a further embodiment, a power cable assembly is provided and includes a power cable that has wires. The power cable assembly includes a power connector that has a connector body holding power terminals terminated to ends of the corresponding power wires forming power lines for the power cable assembly. The power terminals include mating ends configured to be mated with mating terminals of a mating connector. The power connector includes a power health monitoring assembly providing a visual indication of a power health of each of the power lines.

### BRIEF DESCRIPTION OF THE DRAWINGS

FIG. 1 is a perspective view of a power system including power cable assemblies in accordance with an exemplary embodiment.

FIG. 2 is a front perspective view of the power cable assembly including the power health monitoring assembly in accordance with an exemplary embodiment.

FIG. 3 is a rear perspective, partially assembled view of the power cable assembly in accordance with an exemplary embodiment.

FIG. 4 illustrates the power health monitoring assembly in accordance with an exemplary embodiment.

FIG. 5 is a side view of the power cable assembly in accordance with an exemplary embodiment showing the power health monitoring assembly operating in a first configuration.

FIG. 6 is a side view of the power cable assembly in accordance with an exemplary embodiment showing the power health monitoring assembly operating in a second configuration.

FIG. 7 is a side view of the power cable assembly in accordance with an exemplary embodiment showing the power health monitoring assembly operating in a third configuration.

FIG. 8 is a side view of the power cable assembly in accordance with an exemplary embodiment showing the power health monitoring assembly operating in a fourth configuration.

### DETAILED DESCRIPTION OF THE INVENTION

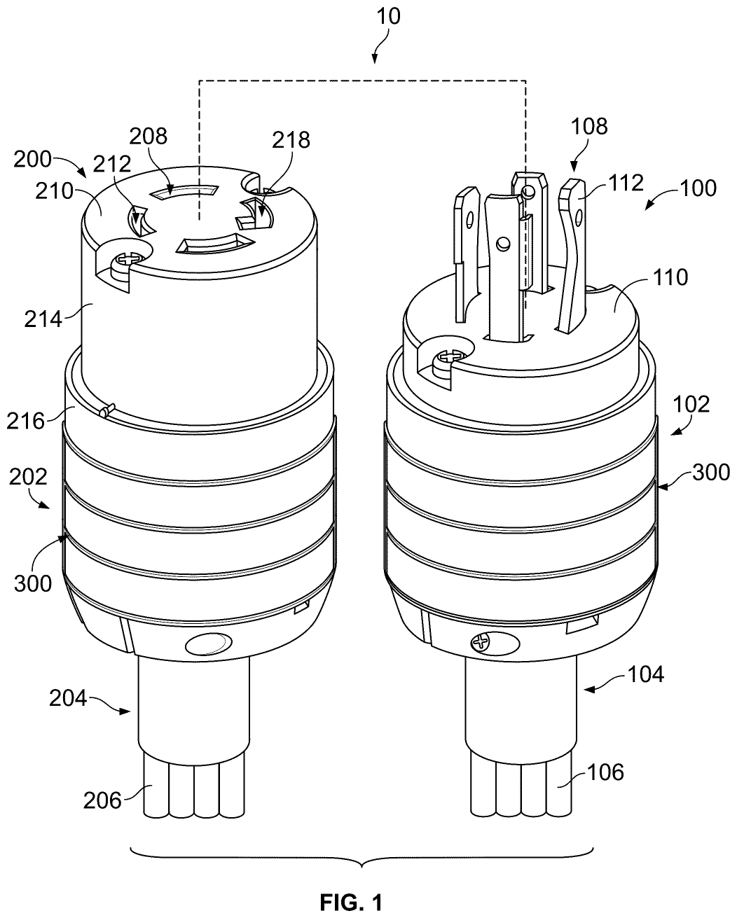

FIG. 1 is a perspective view of a power system 10 including power cable assemblies 100, 200 in accordance with an exemplary embodiment. The power cable assemblies 100, 200 are configured to be mated together along a mating axis to form a power circuit for the power system 10. In the illustrated embodiment, the first power cable assembly 100 is a plug connector and the second power cable assembly 200 is a socket connector. In an exemplary embodiment, the first power cable assembly 100 and/or the second power cable assembly 200 includes a power health monitoring assembly 300.

The power cable assemblies 100, 200 may be high power cable assemblies, such as NEMA rated cable assemblies. The contact configurations of the power cable assemblies 100, 200 can vary dependent on the customers preference or the particular application or equipment incorporating the power cable assemblies 100, 200. The power cable assemblies 100, 200 may supply 125V, 250V, 277V, 480V or other voltages. The power cable assemblies 100, 200 may supply 15 A, 20 A, 30 A, 50 A, 80 A or other amperages. In various embodiments, the power cable assemblies 100, 200 may be 277V A.C. cable assemblies. The power cable assemblies 100, 200 may be 3-phase cable assemblies. The power cable assemblies 100, 200 may be used in various applications across various industries, such as computer servers, charging devices, testing equipment, thermal chambers, industrial equipment, molding equipment, and the like. In various embodiments, the power cable assemblies 100, 200 may be used as AC whip cables to provide AC power input to a power shelf of a server rack; however, the use of the power cables assemblies 100, 200 is not limited to such applications.

The power health monitoring assembly 300 monitors a power health of the power system 10, such as a power health of one or more power circuits or power lines through the first power cable assembly 100 and/or the second power cable assembly 200. In various embodiments, the power health monitoring assembly 300 monitors one or more power characteristics of the power system 10, such as a voltage and/or an amperage of the power line(s) through the first power cable assembly 100 and/or the second power cable assembly 200. The power health monitoring assembly 300 provides a visual indication of the power health of the power system 10, such as for the corresponding power lines through the first power cable assembly 100 and/or the second power cable assembly 200, which is visible from an exterior of the power health monitoring assembly 300. The power health monitoring assembly 300 functions as a quick safety visual aid for the operator to assess the power health characteristics of the individual power lines through the power cable assembly 100. The operator is able to quickly review the lights to confirm that each power line is operating correctly.

The power cable assembly 100 includes a power connector 102 and a power cable 104 extending from the power connector 102. The power cable 104 includes a plurality of wires 106 forming portions of power lines 108 through the power cable assembly 100. The power connector 102 includes a connector body 110 holding power terminals 112 terminated to ends of the corresponding wires 106. The power terminals 112 form portions of the power lines 108 through the power cable assembly 100. The power terminals 112 may be crimped, soldered, welded, or attached by other means such as screws or fasteners to the corresponding wires 106. Any number of the power terminals 112 may be provided depending on the particular application. In the illustrated embodiment, four of the power terminals 112 are provided (for example, hot, hot, neutral, ground). However, greater or fewer power terminals 112 may be provided in alternative embodiments. In alternative embodiments, rather than being terminated to the power cable 104, the power connector 102 may be terminated to another powered element, such as a busbar assembly, a circuit board assembly, or another component, such as directly to an appliance or other powered device thus defining a power header assembly rather than the power cable assembly.

In the illustrated embodiment, the power terminals 112 are male power terminals, such as plug terminals. The power terminals 112 may be blade terminals, pin terminals, or other types of male power terminals. In various embodiments, the power terminals 112 may be twist lock power terminals having a curved profile configured to be locked to the power terminals of the second power cable assembly 200 by a twist locking action. Other types of power terminals may be used in alternative embodiments. In various alternative embodiments, the power terminals 112 of the power cable assembly 100 may be female terminals, such as socket terminals, rather than the male power terminals illustrated in FIG. 1. In various embodiments, the power terminals 112 may include keying features for keyed mating with the mating power terminals of the second power cable assembly 200. The shapes and/or positions of the power terminals 112 may define keyed mating for the first and second power cable assemblies 100, 200 of the power system 10, such as to meet a particular standard terminal pattern.

The power cable assembly 200 includes a power connector 202 and a power cable 204 extending from the power connector 202. The power cable 204 includes a plurality of wires 206 forming portions of power lines 208 through the power cable assembly 200. The power connector 202 includes a connector body 210 holding power terminals 212 terminated to ends of the corresponding wires 206. In an exemplary embodiment, the connector body 210 includes an inner housing 214 and an outer cover 216 surrounding at least a portion of the inner housing 214. The inner housing 214 includes terminal channels 218 that holds the corresponding power terminals 212. In the illustrated embodiment, the power terminals 212 are contained within the inner housing 214. For example, the inner housing 214 completely surrounds the power terminals 212. The power terminals 112 of the first power cable assembly 100 are configured to be plugged into the terminal channels 218 to mate with the power terminals 212. However, in alternative embodiments, the power terminals 212 may extend to an exterior of the inner housing 214 to mate with the power terminals 112 of the first power cable assembly 100.

The power terminals 212 form portions of the power lines 208 through the power cable assembly 200. The power terminals 212 may be crimped, soldered, welded, or attached by other means such as screws or fasteners to the corresponding wires 206. Any number of the power terminals 212 may be provided depending on the particular application. In the illustrated embodiment, four of the power terminals 212 are provided. However, greater or fewer power terminals 212 may be provided in alternative embodiments. In alternative embodiments, rather than being terminated to the power cable 204, the power connector 202 may be terminated to another powered element, such as a busbar assembly, a circuit board assembly, or another component, such as directly to an appliance or other powered device thus defining a power header assembly rather than the power cable assembly.

In the illustrated embodiment, the power terminals 212 are female power terminals, such as socket terminals. In various embodiments, the power terminals 212 may be twist lock power terminals having a curved receptacle configured to receive and lock to the power terminals 112 of the first power cable assembly 100 by a twist locking action. Other types of power terminals may be used in alternative embodiments. In various alternative embodiments, the power terminals 212 of the power cable assembly 200 may be male terminals, such as blade terminals or pin terminals, rather than the female power terminals illustrated in FIG. 1. In various embodiments, the power terminals 212 may include keying features for keyed mating with the mating power terminals 112 of the first power cable assembly 100. The shapes and/or positions of the power terminals 212 may define keyed mating for the first and second power cable assemblies 100, 200 of the power system 20, such as to meet a particular standard terminal pattern.

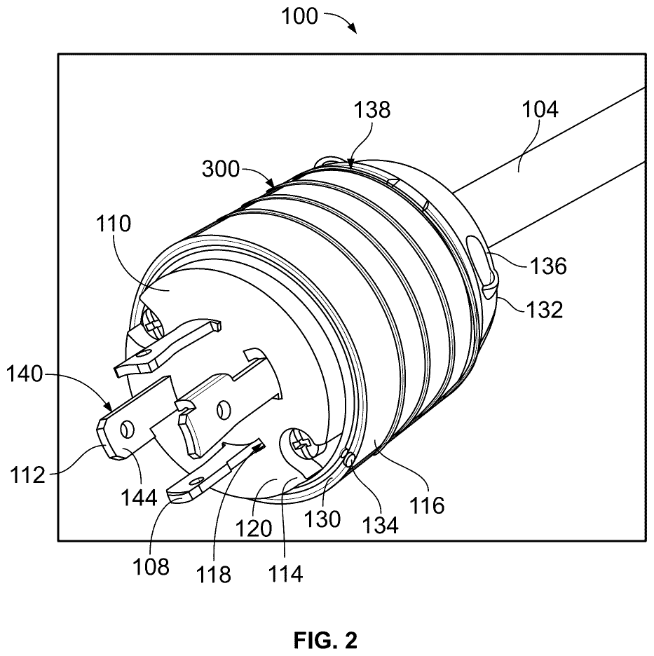

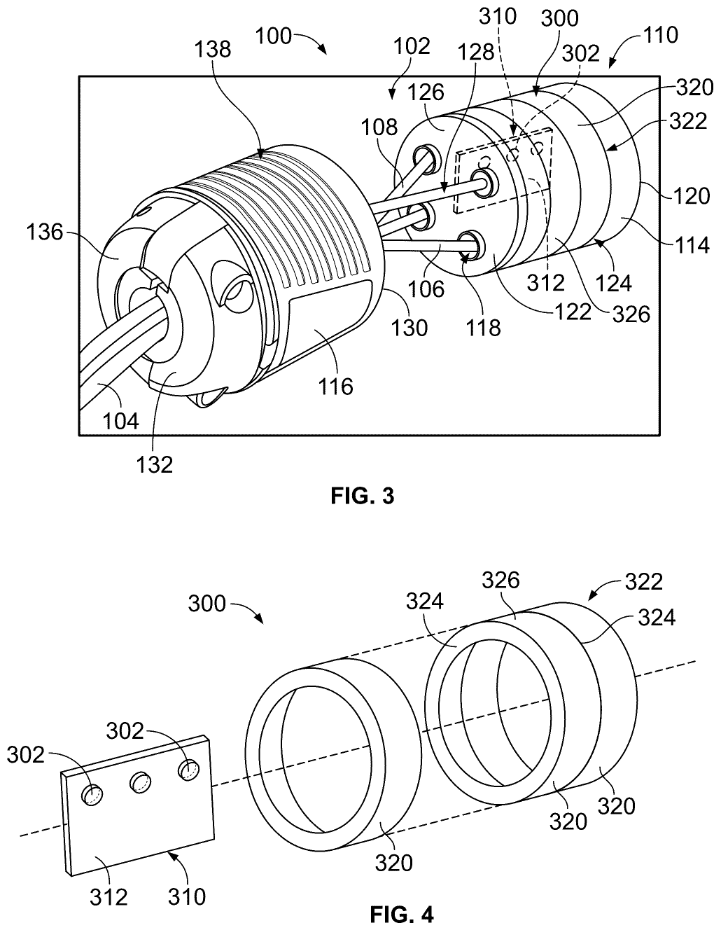

FIG. 2 is a front perspective view of the power cable assembly 100 including the power health monitoring assembly 300 in accordance with an exemplary embodiment. FIG. 3 is a rear perspective, partially assembled view of the power cable assembly 100 in accordance with an exemplary embodiment.

The power cable assembly 100 includes the power connector 102 at the end of the power cable 104. The wires 106 of the power cable 104 are electrically connected to the corresponding power terminals 112 to form the power lines 108 through the power cable assembly 100. In an exemplary embodiment, the connector body 110 of the power connector 102 includes an inner housing 114 and an outer cover 116 surrounding at least a portion of the inner housing 114. The inner housing 114 includes terminal channels 118 that holds the corresponding power terminals 112. The wires 106 may extend into the terminal channels 118 for termination to the power terminals 112. In the illustrated embodiment, the power terminals 112 extend forward from the front of the inner housing 114, such as for mating with the mating power terminals 212 of the second power cable assembly 200 (shown in FIG. 1).

In an exemplary embodiment, the inner housing 114 is manufactured from a dielectric material, such as a plastic or phenolic material. The inner housing 114 extends between a front 120 and a rear 122. In the illustrated embodiment, the inner housing 114 is cylindrical extending along a longitudinal axis between the front 120 and the rear 122. The inner housing 114 may have other shapes in alternative embodiments. In an exemplary embodiment, the inner housing 114 includes one or more pockets 124 that receive components of the power health monitoring assembly 300. The pockets 124 may be provided at the outer perimeter of the inner housing 114, such as along the side between the front 120 and the rear 122.

In an exemplary embodiment, the inner housing 114 includes an endplate 126 at the rear 122. The endplate 126 includes openings 128 that receives the wires 106. The openings 128 are aligned with the terminal channels 118. The endplate 126 may organize the wires 106, such as to align the wires 106 with the terminal channels 118. The endplate 126 may retain the power terminals 112 in the terminal channels 118. The endplate 126 may retain the components of the power health monitoring assembly 300 in the pocket(s) 124. In various embodiments, the endplate 126 is a separate and discrete component configured to be secured to the inner housing 114 using a fastener, such as a screw.

The outer cover 116 is configured to surround the components of the power connector 102, such as the inner housing 114 and/or the endplate 126 and/or the components of the power health monitoring assembly 300. The outer cover 116 extends between a front 130 and a rear 132. The outer cover 116 includes a cavity 134 at the interior of the outer cover 116 that receives the inner housing 114. In various embodiments, the cavity 134 may be open at the front 130 to receive the inner housing 114. The outer cover 116 may include an end wall 136 at the rear 132 two cover the endplate 126. The power cable 104 may pass through the end wall 136.

In an exemplary embodiment, the outer cover 116 is manufactured from a dielectric material, such as a plastic or phenolic material. For example, the outer cover 116 may be a polycarbonate material. In various embodiments, the outer cover 116 includes one or more indication windows 138 in the outer cover 116 for viewing the power health monitoring assembly 300 through the outer cover 116. For example, the outer cover 116 may be transparent at the indication windows 138. Optionally, the entire outer cover 116 may be transparent or translucent to view the power health monitoring assembly 300 through the outer cover 116.

Each power terminal 112 extends between a mating end 140 and a terminating end 142. The mating end 140 is configured to be mated with the mating power terminal 212 of the second power cable assembly 200. In the illustrated embodiment, the mating end 140 extends forward of the inner housing 114. In an exemplary embodiment, the mating end 140 includes a blade contact 144 configured to be mated with the mating power terminal 212. In various embodiments, the blade contact 144 has a curved profile defining a twist lock power terminal. The terminating end 142 is configured to be electrically connected to the corresponding wire 106 of the power cable 104. The terminating end 142 may include a crimped barrel configured to be crimped to the end of the wire 106 or a weld pad configured to be welded to the end of the wire 106. In other various embodiments, the terminating end 142 may include a screw block having a threaded screw threadably coupled to the terminating end 142 for creating a mechanical crimp connection with the wire 106.

With additional reference to FIG. 4, which illustrates the power health monitoring assembly 300 in accordance with an exemplary embodiment, the power health monitoring assembly 300 is configured to be operably connected to the power lines 108 defined by the power terminals 112 and the wires 106 to monitor the power health of the power lines 108. For example, the power health monitoring assembly 300 may be electrically connected to each of the power lines 108 to monitor the voltage, the amperage, or other power health characteristics of the individual power lines 108.

In an exemplary embodiment, the power health monitoring assembly 300 includes indicators 302 operably coupled to each of the power lines 108. For example, the indicators 302 may be electrically connected to the corresponding power terminals 112. The indicators 302 provide a visual indication of a power health of the corresponding power line, which is visible from an exterior of the power connector 102. The indicators 302 are visible through the outer cover 116. In an exemplary embodiment, the indicators 302 include LEDs 304 that generate visible light.

In an exemplary embodiment, the power health monitoring assembly 300 includes a circuit board assembly 310 (shown in phantom in FIG. 3) configured to be received in the connector body 110. For example, the circuit board assembly 310 may be received in a slot in the inner housing 114. The orientation and location of the circuit board assembly 310 may vary in alternative embodiments. The circuit board assembly 310 includes circuits on a substrate 312 of the circuit board assembly 310. The circuits are electrically connected to the power terminals 112 to monitor the health of the various power lines of the power system 10 (for example, hot, ground, neutral). The indicators 302 are electrically connected to the circuits of the circuit board assembly 310 to provide visual indication of the power health of the corresponding power lines. For example, the LEDs 304 may be mounted to the substrate 312, such as being soldered to the substrate 312. In other embodiments, the power health monitoring assembly 300 may include multiple circuit board assemblies 310, such as each associated with a different power line and indicator 302.

In an exemplary embodiment, the power health monitoring assembly 300 includes light pipes 320 optically coupled to the indicators 302 to transfer light from the indicators 302 to a desired location. In an exemplary embodiment, the light pipes 320 are configured to spread the visible light from the indicators 302 to improve visibility of the light emitted from the indicators 302. For example, the light pipes 320 may be enlarged compared to the indicators 302. In an exemplary embodiment, the light pipes 320 are disk shaped to spread the light around the power connector 102. For example, the light pipe 320 may be shaped to provide a generally 360° visibility around the power connector 102 for the corresponding indicator 302. The light pipes 320 may be arranged in a stack 322 along the longitudinal axis of the connector body 110. The light pipes 320 may have other shapes in alternative embodiments.

In an exemplary embodiment, separating panels 324 are provided in the stack 322 between the light pipes 320 to limit bleeding of the light between the light pipes 320 within the stack 322. For example, the separating panels 324 may be opaque to restrict light from passing between the light pipes 320. The separating panels 324 may be separate components from the light pipes 320. Alternatively, the separating panels 324 may be coatings or layers applied to the ends of the light pipes 320 to prevent light from passing through the ends of the light pipes 320. For example, the ends of the light pipes 320 may be painted to form the separating panels 324 on the ends of the light pipes 320.

The light pipes 320 may be coupled to the substrate 312 of the circuit board assembly 310 in alignment with the corresponding indicator 302 to receive the light emitted from the indicator 302. In other various embodiments, the light pipes 320 may additionally or alternatively be coupled to the inner housing 114 and positioned by the inner housing 114 in relation to the indicator 302 to receive the light emitted from the indicator 302. For example, the light pipes 320 may be received in the pocket(s) 124 of the inner housing 114.

The light pipes 320 have exterior surfaces 326 at the radially outer sides of the light pipes 320. The light is emitted through the exterior surfaces 326. The exterior surfaces 326 may be aligned with the exterior side of the inner housing 114. The outer housing 116 may surround the exterior side of the inner housing 114 and the exterior surfaces 326 of the light pipes 320. The light pipes 320 are visible through the transparent outer housing 116.

In an exemplary embodiment, the indicators 302 are electrically connected to the corresponding power lines 108 to monitor a power health characteristic of the corresponding power line 108, such as the voltage, the amperage, or other power health characteristics of the individual power lines 108. For example, the indicators 302 provide a visual indication that the individual power lines 108 are operating properly or operating improperly. For example, the indicators 302 may provide a visual indication that one or more of the power lines have reduced or no voltage or that one or more of the power lines have dropped out of phase.

In an exemplary embodiment, the indicator 302 may be operated in different states based on the power health characteristic that the power health monitoring assembly 300 is monitoring. For example, the indicator 302 may be operated in an ON state if the power line is operating properly and may be operated in an OFF state if the power line is operating improperly. For example, the indicator 302 may be ON if the voltage is above a threshold voltage and may be OFF if the voltage is below a threshold voltage. In various embodiments, the indicator 302 may be operated in a third state if the power line is operating within a particular range or above or below a different threshold. For example, the indicator 302 may be operated at a different power level to output a different intensity or light or operated at a different color (for example, green vs yellow vs red). In some embodiments, multiple indicators 302 may be provided associated with each power line with the multiple indicators 302 operated to provide indication of different power health status for the individual lines. For example, the multiple indicators 302 may operate at different colors to indicate different health ranges, such as normal range (green), abnormal or low range (yellow), and no power (red). In other various embodiments, the multiple indicators 302 may operate to provide visual indication of different health characteristics, such as voltage and amperage.

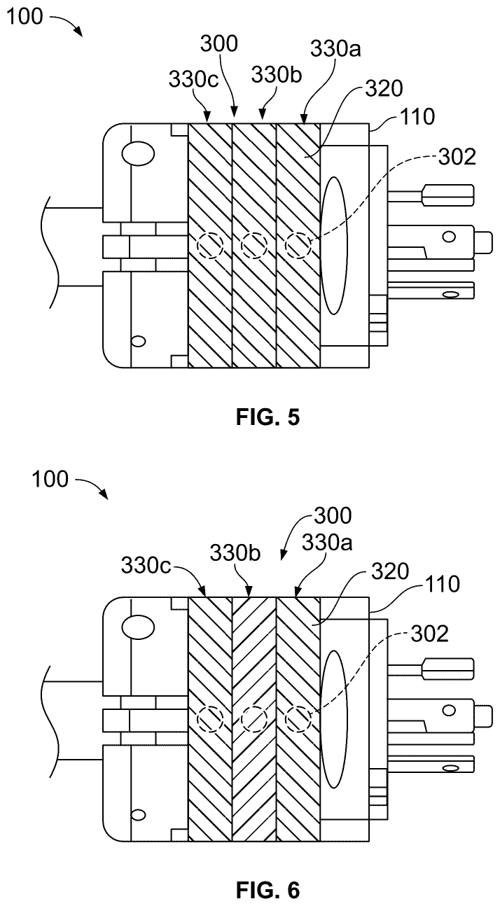

FIG. 5 is a side view of the power cable assembly 100 in accordance with an exemplary embodiment showing the power health monitoring assembly 300 operating in a first configuration showing normal operation status for all of the power lines. FIG. 6 is a side view of the power cable assembly 100 in accordance with an exemplary embodiment showing the power health monitoring assembly 300 operating in a second configuration showing normal operation status for some of the power lines and abnormal operation status for one of the power lines.

In the illustrated embodiment, the power health monitoring assembly 300 includes three indicator units 330 associated with the corresponding power lines, such as the hot, hot and ground power lines of the power cable assembly 100. Each indicator unit includes the indicator(s) 302 and the corresponding light pipe(s) 320 associated with the corresponding power line. The light pipe 320 extends at least partially around the connector body 110. In various embodiments, the light pipe 320 may extend entirely circumferentially around the connector body 110. The light pipe 320 distributes the light from the indicator 302 to a large distribution area to make the visual indication highly visible so the operator can quickly and easily assess the power health of each of the power lines. The power health monitoring assembly 300 functions as a quick safety visual aid for the operator to assess the power health characteristics of the individual power lines through the power cable assembly 100.

In the first configuration (FIG. 5), all three indicator units 330 are activated to indicate normal operation of all three power lines (for example, hot, hot, ground). For example, all three indicators 302 are ON. All three indicators 302 may be the same color, such as green, indicating normal operation. For example, the power health monitoring assembly 300 may monitor the voltage on each power line. The indicator units 330 indicate normal operation when the voltage on the corresponding power line is above a threshold voltage, such as above 105V. Optionally, the indictor units 330 may be programmable to adjust the threshold voltage.

In the second configuration (FIG. 6), two of the indicator units 330a, 330c indicate normal operation. For example, the associated indicators 302 are ON. However, one of the indicator units 330b indicates abnormal operation. For example, the associated indicator 302 is OFF and not illuminated. For example, the indicator unit 330 may indicate abnormal operation when the voltage on the corresponding power line is below the threshold voltage. The operator can quickly and easily determine that the indicator unit 330b is in an OFF state, indicating a problem with one of the power lines. The operator may shut off the device to assess the problem and make any necessary changes or repairs to the power system 10.

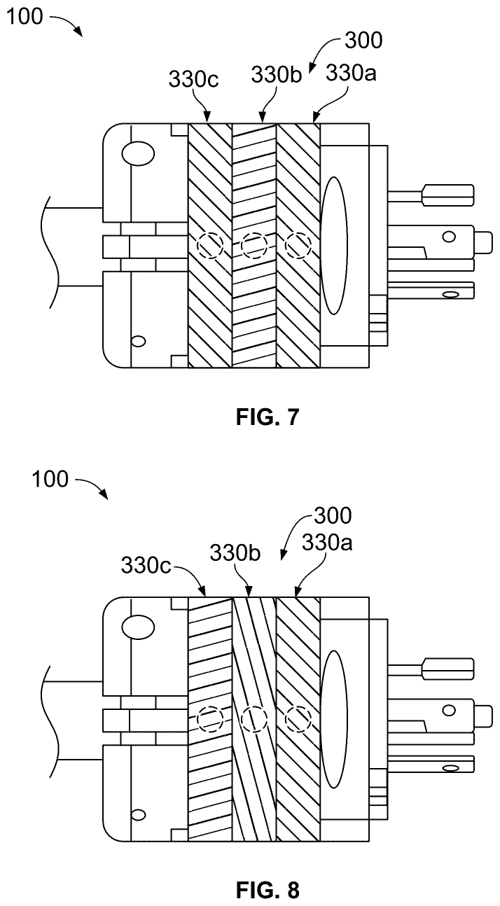

FIG. 7 is a side view of the power cable assembly 100 in accordance with an exemplary embodiment showing the power health monitoring assembly 300 operating in a third configuration. In the third configuration, two of the indicator units 330a, 330c indicate normal operation, while one of the indicator units 330b indicates abnormal operation. For example, the normal indicator units 330a, 330c are ON and may be the same color, such as green, indicating normal operation, whereas the abnormal indicator unit 330b is ON but at a different color, such as red, indicating abnormal operation. The operator can quickly and easily determine that the middle indicator unit 330b is operating in the abnormal state, indicating a problem with one of the power lines. The operator may shut off the device to assess the problem and make any necessary changes or repairs to the power system 10.

FIG. 8 is a side view of the power cable assembly 100 in accordance with an exemplary embodiment showing the power health monitoring assembly 300 operating in a fourth configuration. In the fourth configuration, the first indicator unit 330a indicates normal operation, the second indicator unit 330b indicates abnormal operation, and the third indicator unit 330c indicates abnormal operation. For example, the first indicator unit 330a is ON and may be a first color, such as green, indicating normal operation, such as operation in a normal voltage range (for example, between 105V and 120V). The second indicator unit 330b is ON and may be a second color, such as yellow, indicating abnormal operation, such as operation in a voltage range below the normal voltage range (for example, between 90V and 105V). The third indicator unit 330c is ON and may be a third color, such as red, indicating abnormal operation, such as operation in a voltage range below a threshold voltage (for example, below 90V). The operator can quickly and easily determine the operating states of the indicator units 330 and may determine to shut off the device to assess the problem and make any necessary changes or repairs to the power system 10 based on the operating state, such as if one or more of the indicator units 330 are yellow or red.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112, sixth paragraph, unless and until such claim limitations expressly use the phrase “means for” followed by a statement of function void of further structure.

What is claimed is:

1. A power cable assembly comprising:
a power cable having wires;
a power connector having a connector body holding power terminals terminated to ends of the corresponding power wires forming power lines for the power cable assembly, the power terminals including mating ends configured to be mated with mating terminals of a mating connector, the power connector including a power health monitoring assembly, the power health monitoring assembly including indicators operably coupled to each of the power terminals, the indicators generating visible light and providing a visual indication of a power health of the corresponding power line visible from an exterior of the power connector.

2. The power cable assembly of claim 1, wherein the power health monitoring assembly provides a different visual indication of the power health of each of the power lines individually.

3. The power cable assembly of claim 1, wherein multiple indicators are associated with each power terminal to provide visual indication of different status for each power line.

4. The power cable assembly of claim 3, wherein the indicators are configured to provide visual indication of a normal operation status and the indicators are configured to provide visual indication of an abnormal operation status for each of the power lines.

5. The power cable assembly of claim 1, wherein the power health is based on a voltage of the corresponding power line.

6. The power cable assembly of claim 5, wherein the visual indication is in a first state when the voltage of the power line is above a threshold voltage of the corresponding power line and wherein the visual indication is in a second state when the voltage of the power line is below the threshold voltage of the corresponding power line.

7. The power cable assembly of claim 1, wherein the power health is based on an amperage of the corresponding power line.

8. The power cable assembly of claim 1, wherein the indicators include LEDs.

9. The power cable assembly of claim 1, wherein the connector body includes indication windows for the visual indication of each of the power lines.

10. The power cable assembly of claim 1, wherein the visual indication is visible 360° around the connector body.

11. The power cable assembly of claim 1, wherein the power health monitoring assembly includes a circuit board assembly and conductors between the circuit board assembly and the corresponding power terminals, the indicators being coupled to the circuit board assembly and electrically connected to the corresponding conductors.

12. The power cable assembly of claim 1, wherein the visual indication of the power health includes a first color at a first power health range and a second color at a second power health range.

13. The power cable assembly of claim 12, wherein the visual indication of the power health includes a third color at a third power health range.

14. The power cable assembly of claim 1, wherein the power health monitoring assembly includes a plurality of light pipes, each light pipe being optically coupled to the corresponding indicator to receive and transmit the light from the indicator to an exterior of the light pipe.

15. The power cable assembly of claim 14, wherein the power health monitoring assembly includes separating panels between the light pipes to optically separate the light pipes from each other.

16. A power connector comprising:
a connector body having a mating end configured to be mated with a mating connector, the connector body including an outer surface, the connector body including terminal channels;
power terminals received in the terminal channels, the power terminals including terminating ends and mating ends opposite the terminating ends, the mating ends configured to be mated with mating terminals of the mating connector, the power terminals forming discrete power lines through the power connector;
a power health monitoring assembly held by the connector body, the power health monitoring assembly including indicators operably coupled to each of the power terminals, light from the indicators being visible at the outer surface of the connector body to provide a visual indication of a power health of the corresponding power line.

17. The power connector of claim 16, wherein the power health monitoring assembly provides a different visual indication of the power health of each of the power lines individually.

18. The power cable assembly of claim 16, wherein multiple indicators are associated with each power terminal to provide visual indication of different status for each power line.

19. A power cable assembly comprising:
a power cable having wires;
a power connector having a connector body holding power terminals terminated to ends of the corresponding power wires forming power lines for the power cable assembly, the power terminals including mating ends configured to be mated with mating terminals of a mating connector, the power connector including a power health monitoring assembly providing a visual indication of a power health of each of the power lines.

20. The power cable assembly of claim 19, wherein the power health monitoring assembly provides a different visual indication of the power health of each of the power lines individually.
